(19) United States
(12) Patent Application Publication
(10) Pub. No.: US 2007/0043984 A1
(43) Pub. Date: Feb. 22, 2007

(54) Nonvolatile semiconductor memory device and signal processing system

(76) Inventors: Toshiki Mori, Osaka (JP); Seiji Yamahira, Kyoto (JP)

Correspondence Address: MCDERMOTT WILL & EMERY LLP, 600 13TH STREET, N.W., WASHINGTON, DC, 20005-3096, US

(21) Appl. No.: 11/410,051

(22) Filed: Apr. 25, 2006

(30) Foreign Application Priority Data
Jul. 27, 2005 (JP) 2005-217308

(51) Int. Cl. G11C 29/00

(52) U.S. Cl. 714/718

(57) ABSTRACT

The nonvolatile semiconductor memory device includes: a first memory block having a first program level and a first read circuit; a second memory block having a second program level different from the first program level and a second read circuit of a scheme different from the first read circuit, the second memory block being formed on the same substrate as the first memory block; and a data output circuit for selecting either the first read circuit or the second read circuit and outputting data read via the selected read circuit externally.

### BACKGROUND OF THE INVENTION

The present invention relates to a nonvolatile semiconductor memory device and a signal processing system having a nonvolatile semiconductor memory device, and more particularly, to a technology useful when applied to a nonvolatile semiconductor memory device used in a system in which both codes such as control program codes and data such as images are stored in the nonvolatile semiconductor memory device.

Nonvolatile semiconductor memory devices have found increasingly wide application in information systems and communication systems due to their ability of retaining stored information even after power is turned off. Among others, flash EEPROM (flash memory) permits erasing of an entire chip or in units of blocks to enable reduction in memory cell size and thereby attain low cost. Such flash memory is therefore in sharply increasing demand.

In a system using flash memory, information stored in the flash memory is largely classified into codes (instructions) and data. Codes are instructions executed by a computation processing section in a system LSI. A flash memory for storing such codes must have the ability of reading at high speed codes requested by the computation processing section that operates at high speed. Data such as images handled by application software executed by the system LSI is a high-volume lump of data. A flash memory for storing such data must have the ability of programming and reading such a large lump. of data within a required time.

A flash memory mainly used for storing codes such as instructions is herein defined as a “code flash memory”, and a flash memory mainly used for storing data such as images is herein defined as a “data flash memory”. The performance requirements for each type of memory are summarized in the table shown in FIG. 12. It is found from this table that the performance requirements are different between the code flash memory and the data flash memory in the characteristics of read, program, erase, endurance and the like.

For information stored in the code flash memory, which mainly consists of instructions for the computation processing section, high-speed random access is required. Once such instructions are determined, rewrite of instructions is seldom necessary. Therefore, the requirements for the performance of the endurance, program and erase are not strict. On the contrary, for information stored in the data flash memory, which mainly consists of a large volume of data such as images, while random access performance for read and program is not required, high-speed read and program throughput is required. Since high-speed rewrite is required, high-speed erase is also required and a large number of endurance are required.

An instruction for the computation processing section stored in the code flash memory must be able to be read once the computation processing section requests for read of the instruction even during the time period of access to the data flash memory, in particular, even when program or erase requiring a long time is underway.

A NOR flash memory has performance that suits the requirements for the code flash memory, while a NAND flash memory has performance that suits the requirements for the data flash memory. Therefore, in a system in which codes and data are stored in nonvolatile memory, both a NOR flash memory and a NAND flash memory are used.

For example, a signal processing section of a mobile phone system is constructed of a first system LSI for executing baseband processing and a second system LSI for executing application processing. A NOR flash memory and a DRAM are connected to the first system LSI, while a NOR flash memory, a NAND flash memory and a DRAM are connected to the second system LSI. Codes (instructions) used in the computation processing section of each system LSI are stored in the NOR flash memory of the system LSI, while image data and the like handled by application software executed in the second system LSI are stored in the NAND flash memory.

With the progress of the semiconductor fabrication technology, system LSI is becoming increasingly larger in scale and memory is becoming increasingly larger in capacity. In the mobile phone system described above, if the two system LSIs are united on one chip by use of a further scaling-down process technology, lower cost will be attained. Likewise, further lower cost will be attained if the two DRAMs are united on one chip. The flash memories may also be united on one chip to attain lower cost, but to achieve this, a technology for implementing the code flash memory and the data flash memory having different performance requirements on one chip is necessary.

A composite flash memory that implements flash memories for code storing and for data storing on one chip is disclosed in Japanese Laid-Open Patent Publication No. 10-326493 (Patent Literature 1) and No. 2004-273117 (Patent Literature 2). These disclosures relate to segmentation of a memory into a code storing memory section and a data storing memory section and to a technology permitting read from the code storing memory section during the time period of program or erase operation in the data storing memory section. With the disclosed technology, it is not possible to attain the different read and program performance capabilities required for the code flash memory and the data flash memory as shown in FIG. 12 in the respective flash memories.

Japanese Laid-Open Patent Publication No. 7-281952 (Patent Literature 3) also discloses a technology in which memory cells in a nonvolatile memory array are grouped into a plurality of blocks and, while program or erase operation is underway for a given block, read from another block is allowed. In Patent Literature 3, an address latch is provided for each of the blocks, and an instruction analysis and status data generation section is provided for control of the entire memory chip including the blocks, to analyze instructions for the memory chip, and enable read from a block other than a given block during the time period of program or erase operation for the given block. With the technology disclosed in Patent Literature 3, also, it is not possible to attain the different read and program performance capabilities required for the code flash memory and the data flash memory as shown in FIG. 12 in the respective flash memories.

The technology disclosed in Patent Literature 1 and 2 that permits read from the code storing memory section during the time period of program or erase operation in the data storing memory section is implemented by providing a plurality of memory blocks operable independently from each other, as in the technology disclosed in Patent Literature 3.

Japanese Laid-Open Patent Publication No. 10-27484 (Patent Literature 4) discloses a technology for attaining a plurality of different memory characteristics on one chip. In Patent Literature 4, a NOR memory region is provided inside a NAND memory by replacing some NAND memory cells connected in series to each other with one memory cell. According to Patent Literature 4, by this replacement, a NAND memory that can attain low cost due to its high packing density and a NOR memory excellent in random access performance can be implemented on one chip. However, since the NAND memory and the NOR memory share bit lines and read circuits, the disclosed NOR memory is not applicable to the code flash memory that requires a random read speed higher than the data flash memory by orders of magnitude. Also, the NAND memory and the NOR memory have the same program characteristic, and thus the NAND memory does not provide high-speed program compared with the NOR memory. In addition, it is not allowed to read data from the NOR memory during execution of write or erase operation for the NAND memory.

Japanese Laid-Open Patent Publication No. 11-283382 (Patent Literature 5) discloses a technology for implementing on one chip a program data (code) storing region and a table data (data) storing region that is small in degradation due to rewrite and secures a longer life compared with the program data storing region. By setting the programming voltage applied to the table data storing region at a value lower than the voltage applied to the program data storing region, the programmed threshold voltage for the table data storing region is made lower than the threshold voltage for programming of program data, to thereby enable reduction in the stress during the rewrite and thus secure a longer life. Which region to be accessed, the program data storing region or the table data storing region, is determined from the input address. In Patent Literature 5, the different write threshold voltages are provided by a means for changing the programming voltage, and thus it is not allowed to increase the speed of the program of table data compared with the programming of program data. Also, no description is made on the scheme and circuit for reading data from memory cells set at different programmed threshold voltages. With the disclosed technology, therefore, it is not possible to attain the different read and program performance capabilities required for the code flash memory and the data flash memory as shown in FIG. 12 in the respective flash memories.

Japanese Laid-Open Patent Publication No. 2001-210082 (Patent Literature 6) discloses a technology of switching between multi-value storing and binary storing for each region. Two-value storing is adopted for data requiring high-speed operation and high reliability, while multi-value storing is adopted for data requiring high-volume storing. During programming, a multi-value flag is stored together with program data, and during read, the read sequence is switched according to the value of the flag, to enable arbitrary setting of a binary or multi-value storing region. The disclosed technology is on switching between multi-value storing and binary storing, and unable to achieve high-speed random read and high-throughput read in different memory blocks, which are required as the code flash memory and the data flash memory.

A flash memory as integration of the code flash memory and the data flash memory will not be usable as a product for a system unless the flash memory satisfies all of the two different types of performance requirements at low cost.

As described above, some prior art technologies disclose ways of solving some among many problems that must be solved if it is intended to implement a code memory and a data memory on one chip. However, any combination of these prior art technologies fails to attain the performance requirements for the code flash memory and the data flash memory shown in FIG. 12 on one chip.

### SUMMARY OF THE INVENTION

To overcome the problem described above, the first nonvolatile semiconductor memory device of the present invention includes: a first memory block having a first program level and first read means; a second memory block having a second program level different from the first program level and second read means of a scheme different from the first read means, the second memory block being formed on a same substrate as the first memory block; and data output means for selecting either the first read means or the second read means and outputting data read via the selected read means externally.

The second nonvolatile semiconductor memory device of the present invention includes: a first memory block having first program means for programming information of two or more bits in one memory cell and first read means; a second memory block having second program means different from the first program means and second read means of a scheme different from the first read means, the second memory block being formed on a same substrate as the first memory block; and data output means for selecting either the first read means or the second read means and outputting data read via the selected read means externally.

The third nonvolatile semiconductor memory device of the present invention includes: a first memory block having first word line means for selecting a word line to which given memory cells are connected and first read means; a second memory block having second word line means for selecting a plurality of word lines to which given memory cells are connected and second read means of a scheme different from the first read means, the second memory block being formed on a same substrate as the first memory block; and data output means for selecting either the first read means or the second read means and outputting data read via the selected read means externally.

According to the present invention, a code storing nonvolatile semiconductor memory device and a data storing nonvolatile semiconductor memory device, which are required to have different performance capabilities in the characteristics of read, program, endurance and the like, can be united on one chip and yet satisfy all the performance requirements, and thus price reduction can be attained.

In a system using the nonvolatile semiconductor memory device of the present invention, since the nonvolatile semiconductor memory device, conventionally made up of a plurality of chips, can be implemented on one chip, the packing area can be reduced. Also, since the parasitic capacitance in an address bus and a data bus can be reduced, high-speed operation and low-power operation can be attained.

In addition, read from the code storing region during the time period of program or erase for the data storing region can be achieved with a simple circuit configuration. Therefore, low cost can be attained while the system performance is maintained.

### BRIEF DESCRIPTION OF THE DRAWINGS

FIG. 1 is a block diagram of a flash memory of an embodiment of the present invention.

FIG. 2 is a circuit diagram showing an example of configuration of a common block in FIG. 1.

FIG. 3 shows a threshold voltage distribution for memory cells in FIG. 1.

FIG. 4 shows a programming characteristic for memory cells in FIG. 1.

FIG. 5 is a diagram explaining the timing of program and program-verify for a code memory array in FIG. 1.

FIG. 6 is a diagram explaining the timing of program and program-verify for a data memory array in FIG. 1.

FIG. 7 is a diagram explaining the read timing in the memory of FIG. 1.

FIG. 8 is a diagram explaining the timing of read from the code memory array during the time period of program into the data memory array in the memory of FIG. 1.

FIG. 9 is a circuit diagram showing an example of configuration of a common block in another embodiment of the present invention.

FIG. 10 is a circuit diagram showing an example of configuration of memory cells in yet another embodiment of the present invention.

FIG. 11 is a view showing an example of configuration of a signal processing system using the flash memory of FIG. 1.

FIG. 12 is a table showing performance requirements for the code flash memory and the data flash memory.

### DESCRIPTION OF THE PREFERRED EMBODIMENTS

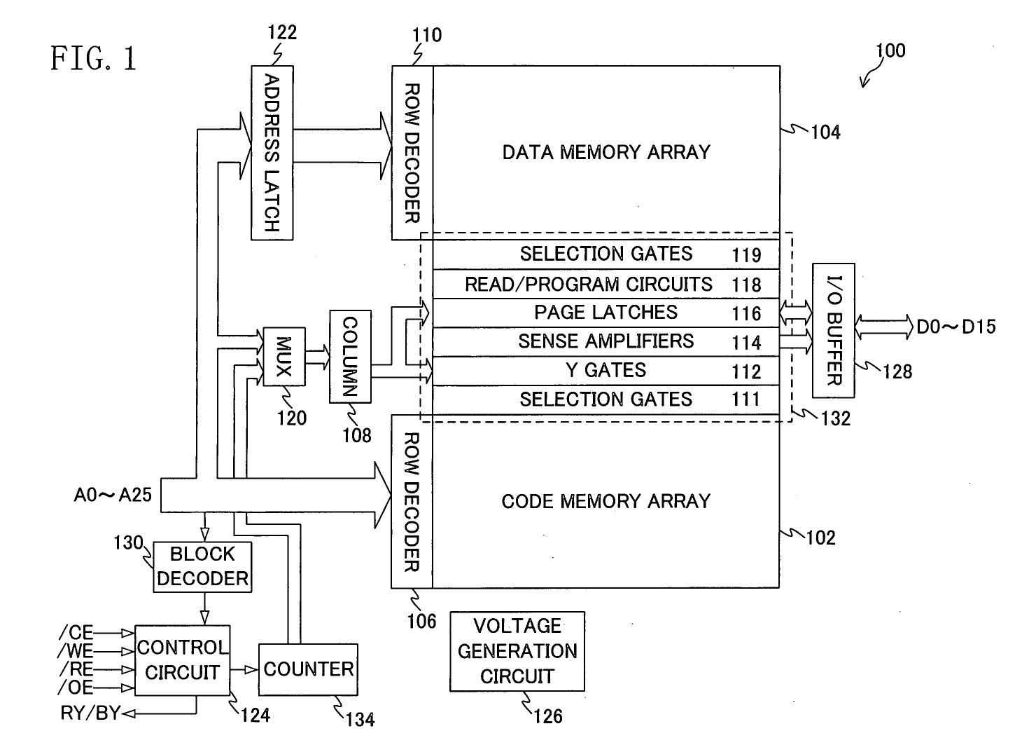

FIG. 1 shows an example of configuration of a flash memory 100 of an embodiment of the present invention. Referring to FIG. 1, the flash memory 100 includes a code memory array 102 adapted to storing codes and a data memory array 104 adapted to storing data. To minimize the fabrication process cost, the code memory array 102 and the data memory array 104 have memory cells of the same structure in the same arrangement. To the code memory array 102 and the data memory array 104, connected are row decoders 106 and 110, respectively, for selecting word lines running in the arrays in response to an input address. Also, sense amplifiers 114 are connected to the code memory array 102 via Y-gates 112, and both page latches 116 and read/program circuits 118 are connected to the code memory array 102 and the data memory array 104 via selection gates 111 and 119, respectively.

A row address input signal from address input terminals A0 to A25 is directly input into the row decoder 106 connected to the code memory array 102 to select a given word line running in the code memory array 102. A signal obtained by latching. the row address input signal from the address input terminals A0 to A25 with an address latch 122 is input into the row decoder 110 connected to the data memory array 104 to select a given word line running in the data memory array 104. A column decoder 108 receives either a column address input signal from the address input terminals A0 to A25 or a signal from a counter 134 whichever is selected by a selection circuit (MUX) 120, and outputs a selection signal for selecting the Y-gates 112 and the page latches 116.

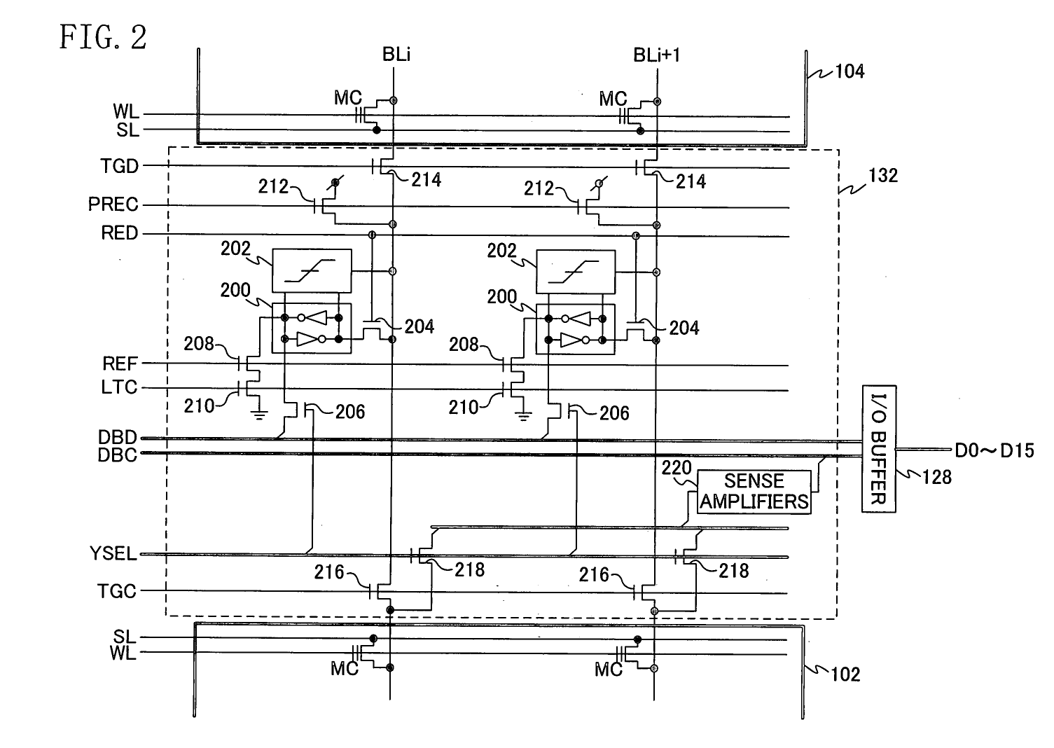

FIG. 2 shows a specific circuit configuration of a common block 132 in FIG. 1 in which the selection gates 111 and 119, the Y-gates 112, the sense amplifiers 114, the page latches 116 and the read/program circuits 118 are placed.

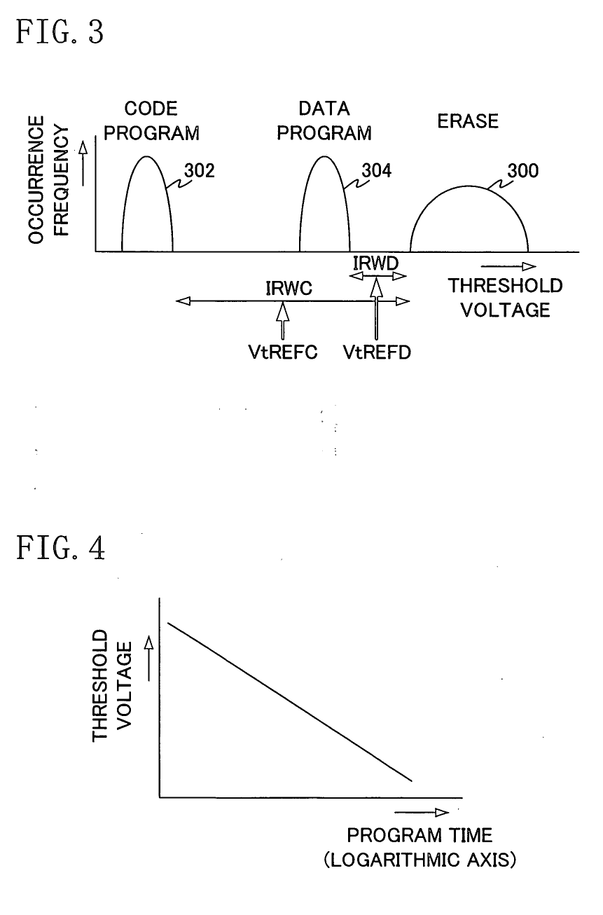

The write threshold voltage for memory cells in the data memory array 104 is set at a value higher than the programmed threshold voltage for memory cells in the code memory array 102. That is, as shown in FIG. 3, the threshold voltage distribution for memory cells in the memory arrays is set so that a programmed threshold voltage distribution 302 for the code memory array 102 is sufficiently low with respect to the erased threshold voltage distribution 300 and that a program threshold voltage distribution 304 for the data memory array 104 is higher than the distribution for the code memory array 102.

FIG. 4 shows a program characteristic for memory cells. As shown in FIG. 4, the threshold voltage for memory cells is proportional to the logarithmic axis of the program time. Therefore, by setting the programmed threshold voltages for memory cells in the code memory array 102 and the data memory array 104 as shown in FIG. 3, the data memory array 104 will reach the target threshold voltage in a shorter time than the code memory array 102 by a time inversely proportional to the exponential function of the potential difference between the threshold voltages. However, as shown in FIG. 3, the threshold voltage width (read window) IRWD between the lower limit of the erased threshold voltage distribution and the upper limit of the programmed threshold voltage distribution for the data memory array 104 is small compared with the threshold voltage width IRWC for the code memory array 102. The read reference current used for read from the code memory array 102 is set at a current corresponding to a threshold voltage VtREFC, and the read reference current used for read from the data memory array 104 is set at a current corresponding to a threshold voltage VtREFD. Therefore, the difference current between a memory cell current and the read reference current is small in the read from the data memory array 104 compared with the read from the code memory array 102.

An exemplary circuit configuration for satisfying both the performance requirements for the code flash memory and the data flash memory shown in FIG. 12, in which the programmed threshold voltages for memory cells in the code memory array 102 and the data memory array 104 are set as shown in FIG. 3, will be described with reference to FIG. 2. Transistors 218 constituting the Y-gates 112 and 1-bit sense amplifiers 220 constituting the sense amplifiers 114 in the common block 132 serve as circuits for random read from the code memory array 102. The components in the common block 132 other than the transistors 218 and the sense amplifiers 220 serve as circuits for read from the data memory array 104 and program into both the data memory array 104 and the code memory array 102. Although FIG. 2 shows the circuit configuration for two bit lines (BLi and BLi+1), substantially the same circuits are connected to all the bit lines.

First, program operation will be described. Each program circuit is shared by the code memory array 102 and the data memory array 104. For which memory array programming is to be performed, the code memory array 102 or the data memory array 104, is determined by turning one of selection gates 214 and 216 ON while the other selection gate OFF. Programming is performed for the memory array connected to the turned-ON selection gate. In the case of programming for the data memory array 104, the selection gate 214 is turned ON with a control signal TGD, and the selection gate 216 is turned OFF with a control signal TGC.

A page latch 200 composed of two inverters cross-connected to each other is connected to the bit line BLi via a transistor 204. Program data is given onto an internal data bus DBD from data input/output (I/O) terminals D0 to D15 via an I/O buffer 128. Data on the internal data bus DBD is selectively taken into the page latch 200 with a transistor 206 driven with a column selection signal YSEL that is output from the column decoder 108 as a result of decoding of the signal from the counter 134. The program data is sequentially input in synchronization with the counting of the counter 134, so that program data of one page corresponding to the number of bit lines is taken into the page latches 200.

The program data taken into each page latch 200 is given to the bit line BLi via a level shift circuit 202. As the data taken into the page latch 200, “1” is a write bit and “0” is a program-prohibit bit. Therefore, only when the data taken into the page latch 200 is “1”, the programming voltage for the drain of a memory cell is given to the bit line BLi. At this time, the transistor 204 has been turned OFF with a control signal RED, and a programming voltage for the control gate of a memory cell into which the program is to be performed has been given to a word line connected to this memory cell from the address latch 122 for latching the row address signal from the address input terminals A0 to A25 and the row decoder 110.

After one unit of program operation for memory cells, it is necessary to verify whether or not each memory cell has reached the target threshold voltage. During this verify operation, with the selection gate 214 being ON with the control signal TGD, the bit line BLi is precharged to a given potential with a control signal PREC via a transistor 212. At the timing of completion of the precharging, a read voltage for the control gate of a memory cell from which read for verify is to be performed is given to a word line connected to the memory cell from the address latch 122 for latching the row address signal from the address input terminals A0 to A25 and the row decoder 110, to allow discharge of the precharge level at the bit line with the current flowing in the memory cell. The transistor 204 is turned ON under the control with the control signal RED at predetermined timing, to allow the potential at the bit line to be given to the page latch 200. A transistor 208 receiving a reference voltage REF at its gate and a transistor 210 receiving a latch timing control signal LTC at its gate are connected in series to the other terminal of the page latch 200, to allow comparison of the bit line potential with the reference voltage REF at the control timing of the latch timing control signal LTC, to thereby determine whether or not the memory cell has reached the target threshold voltage. The page latch 200 connected the memory cell determined to have reached the target threshold voltage inverts the latched data according to the comparison result, to turn the stored data to “0” indicating program prohibit.

If the program data in the page latch 200 is determined to have not reached the target threshold voltage as a result of the verify operation by comparing the bit line potential with the reference voltage REF, the data is kept unchanged. As long as there exists a bit that has not reached the target threshold voltage, next program and program-verify operation is repeated.

Once all bits are determined to have reached the target threshold voltage after the program-verify operation, a program completion signal is issued by a program completion detection means (not shown), to terminate the program.

In the case of program for the code memory array 102, the selection gate 214 is turned OFF while the selection gate 216 is turned ON, and substantially the same operation as the program for the data memory array 104 is performed. In this case, however, the reference voltage REF given to the transistor 208 during the program-verify is set at a voltage different from that given during the program-verify for the data memory array 104, to permit setting of the threshold voltage for memory cells for determining program completion at a value different from that used during the program for the data memory array 104.

In the manner described above, by setting the programmed threshold voltage for the data memory array 104 at a voltage higher than that for the code memory array 102, the program speed for the data memory array 104 can be made markedly high compared with that for the code memory array 102.

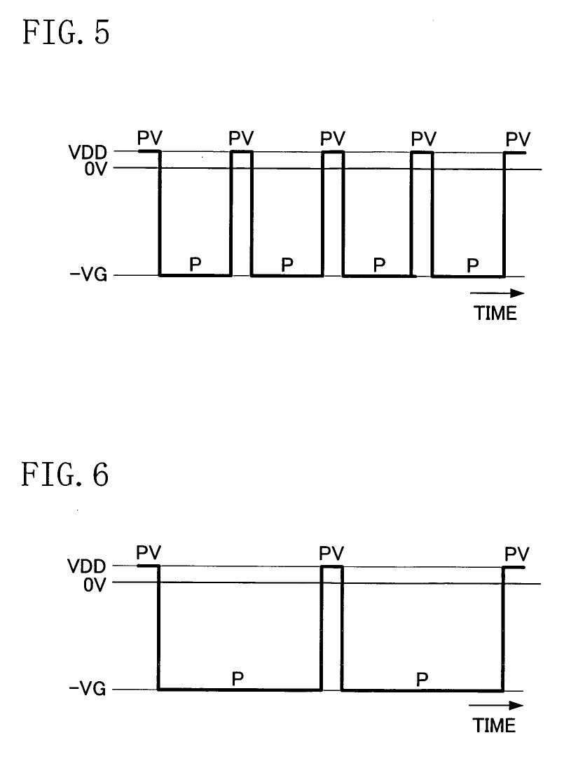

Next, a method for further increasing the program speed for the data memory array 104 will be described. As described above, in the program operation, program operation for memory cells and read operation for program-verify are executed repeatedly. Since the programmed threshold voltage for the code memory array 102 is set at a low value, strict control for the programmed threshold voltage is required. If the programmed threshold voltage is excessively low and some memory cells become 0 V or less, a drain-source leak current may occur even during the non-selected time, and this will cause erroneous read from selected memory cells. To avoid this problem, programming control must be made in which the pulse width during the programming is set small as shown in FIG. 5, to reduce the width of variation of the threshold voltage in one unit of write operation. In FIG. 5, P denotes the program time period and PV denotes the program-verify time period.

On the contrary, since the programmed threshold voltage for the data memory array 104 is set at a high value, even if the width of variation of the programmed threshold voltage is large compared with that for the code memory array 102, memory cells will not generate a leak current that may cause erroneous read as described above. Therefore, the control of the programmed threshold voltage can be less tightened compared with. that for the code memory array 102. Accordingly, for the programming for the data memory array 104, the program pulse width can be set large compared with that for the code memory array 102 as shown in FIG. 6, to reduce the number of times of repetition of the program and the program-verify. Thus, further high programming speed for the data memory array 104 can be attained.

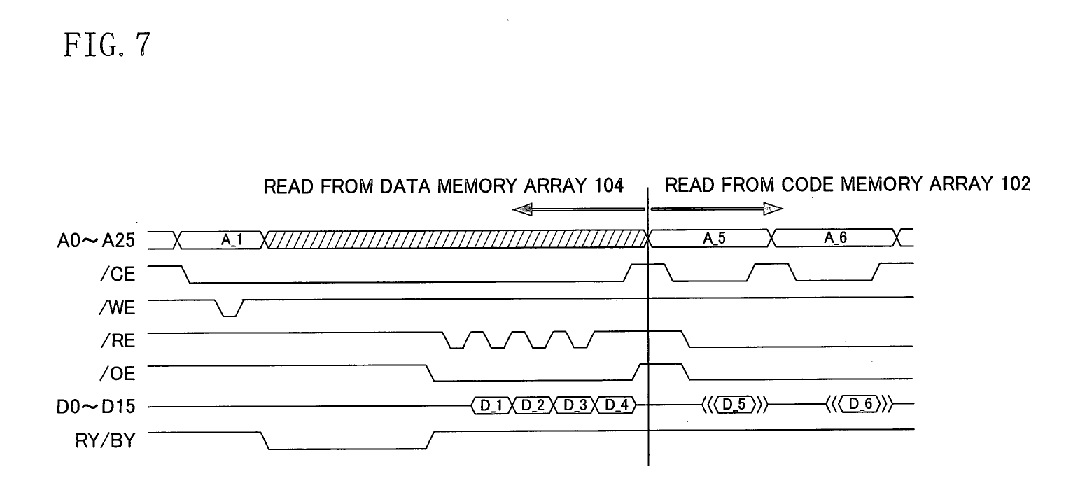

Next, read operation will be described with reference to the timing chart (former part) of FIG. 7. In the case of read from the data memory array 104, substantially the same operation as the program-verify is performed. A row address A_1 from the address input terminals A0 to A25 is taken into the address latch 122 with a write enable signal/WE and given to the row decoder 110. The row decoder 110 selects a given word line according to the input address A_1. When read is started, a ready/busy signal RY/BY is set at “0” indicating the busy state.

Simultaneously with the selection of a given word line, substantially the same operation as the program-verify is performed while the selection gates 216 being kept in the OFF state. At this time, by setting the reference voltage REF given to the transistors 208 at a potential for read, data stored in memory cells connected to the word line selected by the row decoder 110 can be read to the page latches 200 for each page. Once the stored data in the memory cells is read to the page latches 200, the ready/busy signal RY/BY is set at “1” indicating the ready state. When the signal/RE is pulsed in response to the this change of the read/busy signal, the counter 134 starts counting, and the data is selectively output onto the internal data bus DBD via the transistors 206 with the column selection signal YSEL output from the column decoder 108 as a result of decoding of the signal from the counter 134. As the counter 134 sequentially counts, memory cell data read to the page latches 200 is sequentially output onto the internal bus DBD, and then sequentially output to the data I/O terminals D0 to D15 via the I/O buffer 128 as shown by D_1, D_2, D_3 and D_4.

As described above with reference to FIG. 3, the programmed threshold voltage for memory cells in the data memory array 104 is set at a higher value than the programmed threshold voltage for memory cells in the code memory array 102. Therefore, for the data memory array 104, the difference current between the memory cell current during the read and the read reference current is small, and thus it is difficult to attain high-speed read. For this reason, it takes a long time to take data into the page latches 200. However, by taking data of one page into the page latches 200 at one time and sequentially changing the column address, the data in the page latches 200 can be sequentially output to the I/O terminals D0 to D15 in a short time. In this way, high-speed read throughput can be attained.

Read from the code memory array 102 that requires high-speed random access will be described with reference to the timing chart (latter part) of FIG. 7. When an address signal A_5 is input from the address input terminals A0 to A25 and a chip enable signal/CE is asserted, the row decoder 106 selects a word line to which memory cells to be accessed are connected according to the received row address, and the column decoder 108 receives a column signal selected by the selection circuit 120 and outputs the column selection signal YSEL according to the received address, to thereby control the transistors 218 constituting the Y-gates 112. With this operation, 16 bit lines BLi (i=0 to 15) are selectively connected to the sense amplifiers 220, to permit a memory cell current flowing via each bit line connected to the sense amplifier 220 to be converted to a voltage, which is then output to an internal bus DBC. The data on the internal bus DBC is output to the data I/O terminal D0 to D15 via the I/O buffer 128 as D_5. When different memory cells are to be selected and read, a different address signal A_6 is given from the address input terminals A0 to A25 and the chip enable signal/CE is asserted. Data stored in the memory cells selected according to the input address A_6 is output to the data I/O terminal D0 to D15 as D_6 in substantially the same manner as that described above.

The programmed threshold voltage for memory cells in the code memory array 102 is set at a value sufficiently lower than the programmed threshold voltage for memory cells in the data memory array 104. Therefore, a large value is obtained as the difference current between the memory cell current and the read reference current, and thus the parasitic capacitance of a bit line can be charged/discharged at high speed. Also, since only a small number of sense amplifiers 220, which is equivalent to the I/O data width (16 in this embodiment), is required, a circuit configuration permitting high-speed read can be adopted, and thus high-speed random access can be attained.

As for erase operation, an erase voltage is applied to the code memory array 102 and the data memory array 104 in substantially the same manner as that described above. Since the programmed threshold voltage for the data memory array 104 is high and thus small in the potential difference from the post-erase threshold voltage, compared with that for the code memory array 102, erase can be done at a high speed for the data memory array 104 than for the code memory array 102 as in the case of program.

Since the potential difference between the programmed threshold voltage and the erased threshold voltage is smaller for the data memory array 104 than for the code memory array 102, memory cells are less stressed during rewrite operation, and thus the number of times of rewrite can be larger for the data memory array 104 than for the code memory array 102.

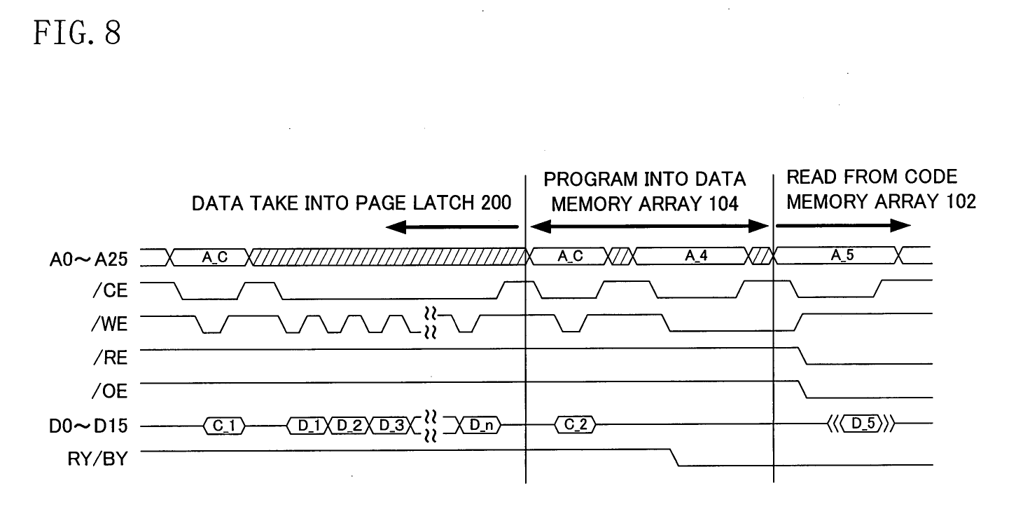

Next, the case of executing read from the code memory array 102 during the time period of write into the data memory array 104 will be described with reference to FIG. 8. For program into the data memory array 104, data is first taken into the page latches 200. A signal A_C indicating that it is in the command input time period is given to the address input terminals A0 to A25, and simultaneously, a command C_1 indicating that it is in the program data taking mode is input into the data I/O terminal D0 to D15. Subsequently, program data D_1, D_2, D_3, . . . , D_n are sequentially given in synchronization with pulses of the signal/WE. The column decoder 108 decodes the output of the counter 134 counting the pulses of the signal/WE to sequentially control the transistors 206. In this way, program data of one page is taken into the page latches 200.

Once the taking of the program data into the page latches 200 is completed, program operation for the data memory array 104 is executed. The signal A_C indicating that it is in the command input time period is given to the address input terminals A0 to A25, and simultaneously, a command C_2 indicating that it is in the program mode is input into the data I/O terminals D0 to D15. Subsequently, an address A_4 is given for selection of memory cells in the data memory array 104 into which the data is to be programmed, and the signal/WE is set at “0” to start program operation. At this time, the ready/busy signal RY/BY becomes “0” indicating the busy state. When an address A_5 indicating a region in the code memory array 102 is given to the address input terminals A0 to A25 during the time period in which the program into the data memory array 104 is underway, the memory starts read operation from the code memory array 102 while executing the program and program-verify operation for the data memory array 104. Since the selection gate 216 is kept in the OFF state during the time period of program and program-verify operation for the data memory array 104, the read operation for the code memory array 102 using the Y-gate transistors 218 and the sense amplifiers 220 can be executed without being affected by the program and program-verify operation for the data memory array 104. Therefore, once the address signal A_5 is received from the address input terminals A0 to A25 and the signal/CE is asserted, memory cells in the code memory array 102 are selected, and data read from the selected memory cells is output to the data I/O terminals D0 to D15 as D_5. The ready/busy signal RY/BY is kept at “0” indicating the busy state until the program into the data memory array 104 is completed.

As described above, with the circuit configuration shown in FIGS. 1 and 2 and the setting of the programmed threshold voltage for the data memory array 104 higher than that for the code memory array 102, a flash memory satisfying both the requirements for the code flash memory and the data flash memory shown in FIG. 12 can be implemented on one chip.

The data memory array 104 is used for storing high volumes of data such as images and thus is large in capacity compared with the code memory array 102. Therefore, it will be very useful if the data memory array 104 can be implemented at low cost compared with the code memory array 102.

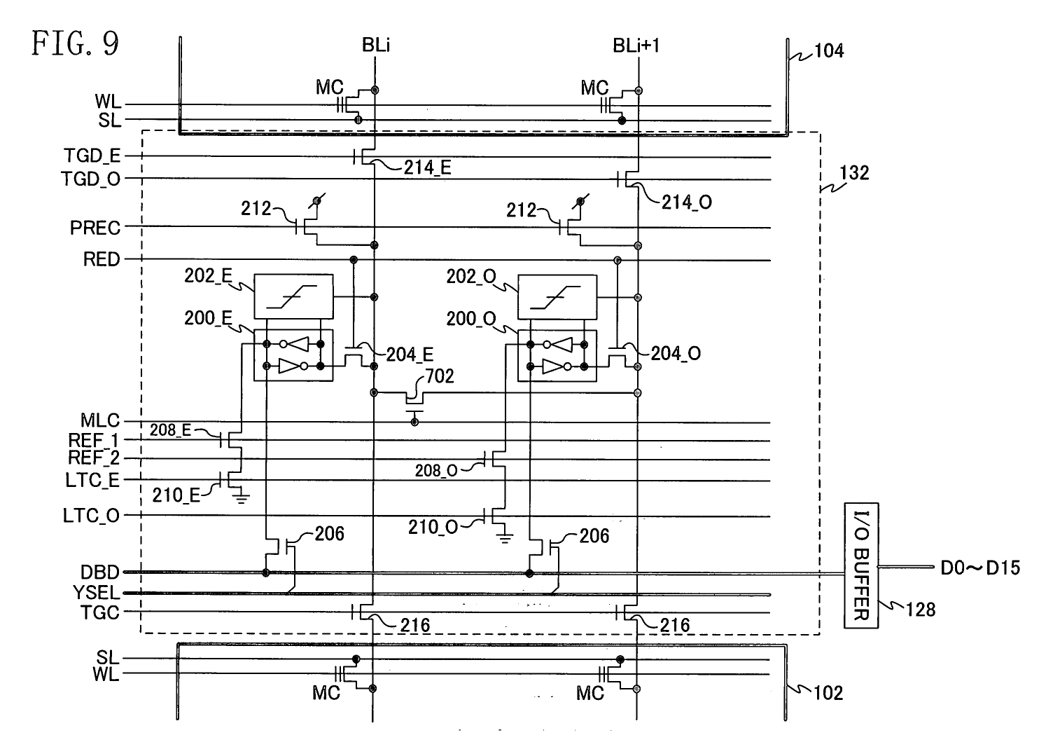

Hereinafter, a means for implementing the data memory array 104 at low cost compared with the code memory array 102 will be described. FIG. 9 shows a circuit configuration in which 2-bit information is programmed into one memory cell in the 4-value level for the data memory array 104, while 1-bit information is programmed into one memory cell in the binary level for the code memory array 102. Note that the same components as those in FIG. 2 are denoted by the same reference numerals, and that the Y-gate transistors 218, the sense amplifiers 220 and the internal bus DBC as the circuits for read from the code memory array 102 are omitted in FIG. 9 as these are the same in configuration and operation as in FIG. 2. The different points from FIG. 2 are that a selection transistor 702 is additionally placed between the bit lines BLi and BLi+1 and that the signal TGD for controlling the selection gates 214 is divided into TGD_E and TGD_O, the signal LTC input into the gates of the transistors 210 for controlling the timing of taking data in memory cells into the page latches 200 during the read and the program-verify is divided into LTC_E and LTC_O, and the reference voltage REF given to the transistors 208 during the read and the program-verify is divided into REF_1 and REF_2.

In the case of program of 1-bit information into one memory cell in the code memory array 102 in the binary level, the selection transistor 702 is kept in the OFF state under the control with a signal MLC, and the timing control signals LTC_E and LTC_O, the control signals TGD_E and TGD_O and the reference voltages REF_1 and REF_2 are respectively controlled as the same signals, to execute substantially the same operation as that described above with reference to FIG. 2. The program can therefore be done as described above with reference to FIG. 2. As for read of binary information from the code memory array 102, substantially the same operation as that described above with reference to FIG. 2 is executed using the Y-gate transistors 218, the sense amplifiers 220 and the internal bus DBC not shown.

The case of program of 2-bit information into one memory cell in the data memory array 104 in the 4-value level will be described. Page latches 200_E and 200_O connected to the bit lines BLi and BLi+1 respectively take first-bit information and second-bit information for program into one memory cell. The taking procedure is as described above with reference to FIG. 2. That is, program data input via the data I/O terminals D0 to D15 is taken from the internal bus DBD via the transistors 206 according to the column selection signal YSEL given from the column decoder 108. The 2-bit program data taken into the two page latches 200_E and 200_O is programmed into a memory cell connected to the bit line BLi in the 4-value level in the following procedure.

First, while a selection gate 214_O is kept in the OFF state with the control signal TGD_O, a selection gate 214_E is turned ON with the control signal TGD_E, to thereby enable program into a memory cell connected to the bit line BLi. The program operation is made for each of the 2 -bit program data taken into the page latches 200_E and 200_O. In program of the first bit into a memory cell, if the program data taken into the page latch 200_E is “1” indicating the program bit, the programming voltage is given from a level shift circuit 202_E to the drain of the memory cell via the bit line BLi. In program of the second bit into the memory cell, if the program data taken into the page latch 200_O is “1” indicating the program bit, the programming voltage is given from a level shift circuit 202_O to the bit line BLi via the selection transistor 702. In the program of the first and second bits, a programming voltage for the control gate of the memory cell into which the program is to be performed has been given to a word line connected to the memory cell from the address latch 122 for latching the row address from the address input terminals A0 to A25 and the row decoder 110.

After the execution of the program of the first and second bits, program-verify is executed. The selection transistor 702 and the selection gate 214_E connected to the bit line BLi are turned ON with the control signal MLC and the control signal TGD_E, respectively, while the selection gate 214_O is turned OFF with the control signal TGD_O. The bit line BLi is precharged to a given potential via the transistor 212 with the control signal PREC. At the timing of completion of the precharging, a read voltage for verify operation for the control gate of the memory cell from which read is to be performed is given to the word line connected to the memory cell from the address latch 122 for latching the row address from the address input terminals A0 to A25 and the row decoder 110. With the current flowing in the selected memory cell, the precharge level of the bit line BLi is discharged. At this time, since the selection gate 214_O connected to the bit line BLi+1 is kept in the OFF state, no read from a memory cell connected to the bit line BLi+1 is performed.

Under the control with the control signal RED at predetermined timing, transistors 204_E and 204_O are turned ON to allow the potential at the bit line BLi. to be given to the page latches 200_E and 200_O. A transistor 208_E receiving the reference voltage REF_1 at its gate and a transistor 210_E receiving the latch timing control signal LTC_E at its gate are connected in series to the other terminal of the page latch 200_E. Also, a transistor 208_O receiving the reference voltage REF_2 at its gate and a transistor 210_O receiving the latch timing control signal LTC_O at its gate are connected in series to the other terminal of the page latch 200_O. At the control timing with the latch timing control signals LTC_E and LTC_O, the potential at the bit line BLi is compared with the reference voltage REF_1 for the first bit and the reference voltage REF_2 for the second bit in the page latches 200_E and 200_O, to individually determine whether or not the memory cell has reached the threshold voltage for the first bit in the page latch 200_E and whether or not the memory cell has reached the threshold voltage for the second bit in the page latch 200_O. If it is determined that the memory cell has reached the threshold voltage in the individual determination, the data “1” indicating the program bit in the page latches 200_E and 200_O is inverted to “0”. On the contrary, if it is determined that the memory cell has not reached the threshold voltage, the data “1” indicating the program bit in the page latches 200_E and 200_O is kept unchanged. As long as the “1” data is retained in the page latches 200_E and 200_O, the program and program operation is repeated. If it is determined that all bits have reached the target threshold voltages after the program and verify operation, a programming completion signal is issued by a write completion detection means (not shown) to complete the program operation.

As described above, in the program-verify operation, by setting the reference voltages REF_1 and REF_2 at potentials corresponding to the values of the 2-bit program data, the 2-bit program data taken into the page latches 200_E and 200_O can be programmed into one memory cell in the data memory array 104 in the 4-value level.

Read of data stored in the 4-value level from the data memory. array 104 is substantially the same as the read in the proram-verify operation, in which 2-bit data is read from one memory cell to the page latches 200_E and 200_O, and is sequentially output to the data I/O terminals D0 to D15 via the internal bus DBD and the I/O buffer 128 with the selection signal YSEL from the column decoder 108, as in the case of data stored in the 2-value level.

In the case of write of 2-bit program data taken into the page latches 200_E and 200_O into a memory cell connected to the bit line BLi+1, substantially the same operation as the program into a memory cell connected to the bit line BLi described above can be executed by turning the selection gate 214_E OFF with the control signal TGD_E while turning the selection gate 214_O ON with the control signal TGD_O.

As described above, by storing 2-bit data in memory cells in the data memory array 104, the data memory array 104 can be implemented at low cost, compared with the code memory array 102 storing 1-bit data, even though the code memory array 102 and the data memory array 104 are composed of memory cells of the same structure.

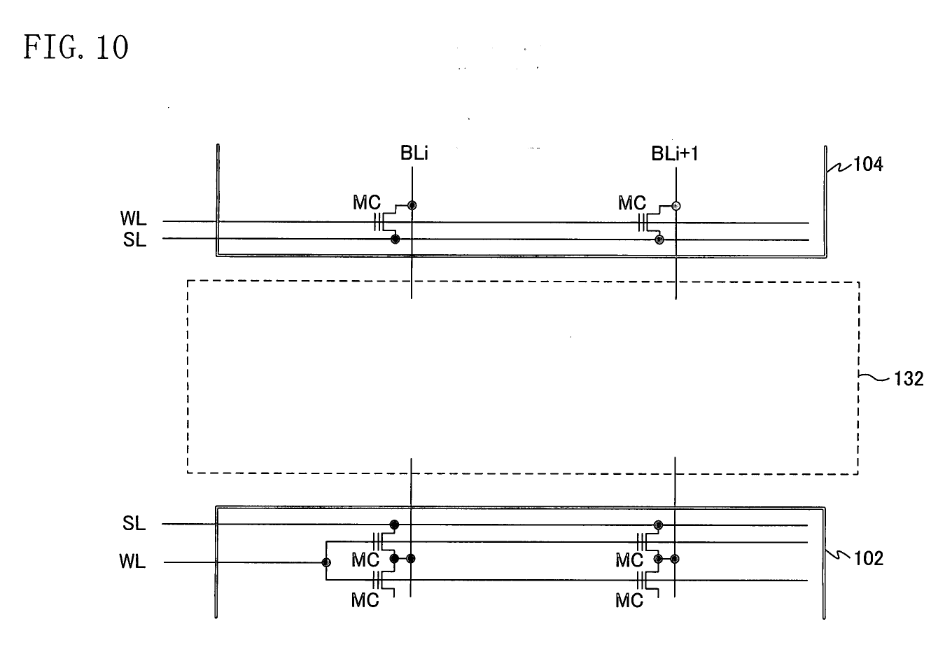

FIG. 10 shows another embodiment for implementing the data memory array 104 at low cost compared with the code memory array 102. In FIG. 10, the code memory array 102 and the data memory array 104 are composed of memory cells of the same structure, and assume that these memory cells are the minimum memory cells available in the semiconductor fabrication process technology. In the data memory array 104, memory cells are arranged at the respective crossings of word lines and bit lines. On the contrary, in the code memory array 102, a plurality of word lines are made selectable with one address, and a plurality of memory cells are involved for one bit, to secure. a memory cell current necessary to attain a required read speed. With the memory cell configuration described above, the high-speed random read requested for the code flash memory and the high program throughput and high read throughput requested for the data flash memory can be attained with low-cost memory arrays.

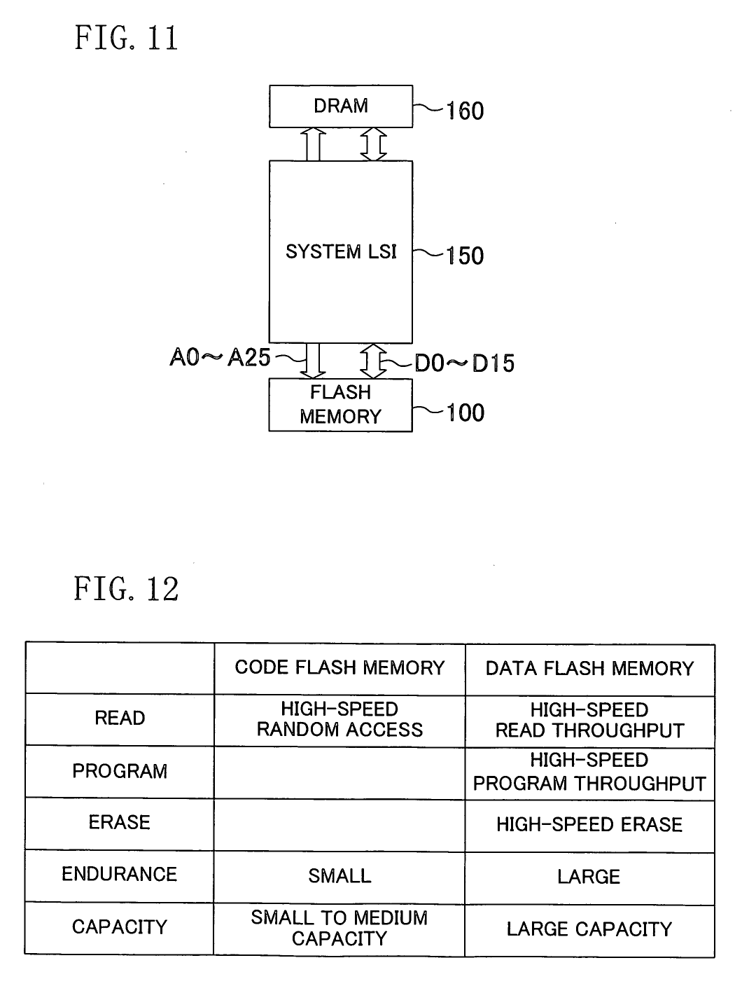

In the mobile phone system described earlier, with the progress of the semiconductor fabrication technology, two system LSIs can be united on one chip, and two DRAMs can be united on one chip. By using the flash memory 100 shown in FIG. 1, the system can be implemented in a significantly simplified configuration as shown in FIG. 11, in which the reference numeral 150 is a united system LSI and 160 is a united DRAM.

As described above, the nonvolatile semiconductor memory device and the signal processing system according to the present invention present a technology permitting low cost and a small packing area, and are applicable to, not only systems that store both codes and data, but also unification of nonvolatile memory devices having a plurality of different performance requirements.

What is claimed is:

1. A nonvolatile semiconductor memory device comprising:
a first memory block having a first program level and first read means;
a second memory block having a second program level different from the first program level and second read means of a scheme different from the first read means, the second memory block being formed on a same substrate as the first memory block; and
data output means for selecting either the first read means or the second read means and outputting data read via the selected read means externally.

2. The device of claim 1, wherein an internal bus different from an internal data bus used for program and read into/from the first memory block is used for read from the second memory block.

3. The device of claim 1, further comprising:
block decode means for determining which block, the first memory block or the second memory block, is to be accessed from part of an input address; and
control signal generation means that switches the timing of read and program according to the output of the block decode means.

4. The device of claim 1, wherein the second memory block is constructed of arrangement of memory cells of the same structure as memory cells arranged in the first memory block.

5. The device of claim 1, wherein the second memory block has a second program-verify reference potential different from a first program-verify reference potential for the first memory block.

6. The device of claim 1, wherein the second memory block has second program-verify timing generation means different from first program-verify timing generation means for the first memory block.

7. A signal processing system comprising:
the nonvolatile semiconductor memory device of claim 1; and
an operation LSI connected to the nonvolatile semiconductor memory device via an address bus and a data bus.

8. A nonvolatile semiconductor memory device comprising:
a first memory block having program write means for programming information of two or more bits in one memory cell and first read means;
a second memory block having second program means different from the first program means and second read means of a scheme different from the first read means, the second memory block being formed on a same substrate as the first memory block; and
data output means for selecting either the first read means or the second read means and outputting data read via the selected read means externally.

9. The device of claim 8, wherein an internal bus different from an internal data bus used for program and read into/from the first memory block is used for read from the second memory block.

10. The device of claim 8, further comprising:
block decode means for determining which block, the first memory block or the second memory block, is to be accessed from part of an input address; and
control signal generation means that switches the sequence and timing of program and the timing of read according to the output of the block decode means.

11. The device of claim 8, wherein the second memory block is constructed of arrangement of memory cells of the same structure as memory cells arranged in the first memory block.

12. A signal processing system comprising:
the nonvolatile semiconductor memory device of claim 8; and
an operation LSI connected to the nonvolatile semiconductor memory device via an address bus and a data bus.

13. A nonvolatile semiconductor memory device comprising:
a first memory block having first word line means for selecting a word line to which given memory cells are connected and first read means;
a second memory block having second word line means for selecting a plurality of word lines to which given memory cells are connected and second read means of a scheme different from the first read means, the second memory block being formed on a same substrate as the first memory block; and
data output means for selecting either the first read means or the second read means and outputting data read via the selected read means externally.

14. The device of claim 13, wherein an internal bus different from an internal data bus used for program and read into/from the first memory block is used for read from the second memory block.

15. The device of claim 13, wherein the second memory block is constructed of arrangement of memory cells of the same structure as memory cells arranged in the first memory block.

16. A signal processing system comprising:
the nonvolatile semiconductor memory device of claim 13; and
an operation LSI connected to the nonvolatile semiconductor memory device via an address bus and a data bus.

17. A nonvolatile semiconductor memory device comprising:
a first memory block;
a second memory block formed on a same substrate as the first memory block;
program means shared by the first memory block and the second memory block;
first read means shared by the first memory block and the second memory block for performing program-verify;
data input means for inputting write data into the program means;
second read means for performing read from the second memory block via a path different from the first read means; and
data output means for selecting either the first read means or the second read means and outputting data read via the selected read means externally.

18. The device of claim 17, wherein the second read means for read from the second memory block adopts a scheme different from the first read means for read from the first memory block.

19. The device of claim 17, wherein data input into the data input means for inputting program data into the program means and data output from the second read means for read from the second block means are performed at a same terminal via same data input/output means.

20. A signal processing system comprising:
the nonvolatile semiconductor memory device of claim 17; and
an operation LSI connected to the nonvolatile semiconductor memory device via an address bus and a data bus.

21. A nonvolatile semiconductor memory device comprising:
a first memory block;
a second memory block formed on a same substrate as the first memory block;
a first selection gate connected to a bit line in the first memory block;
a second selection gate connected to a bit line in the second memory block;
program means for the first memory block and the second memory block connected between the first selection gate and the second selection gate;
first read means connected between the first selection gate and the second selection gate for performing read from the first memory block and the second memory block;
data input means for inputting program data into the program means;
third selection gate connected to a bit line in the second memory block;
second read means selectively connected to a bit line in the second memory block via the third selection gate; and
data output means for selecting either data read from the first memory block with the first read means or data read from the second memory block with the second read means, and outputting the selected read data externally.

22. The device of claim 21, wherein the second read means for read from the second memory block adopts a scheme different from the first read means for read from the first memory block.

23. The device of claim 21, wherein data input into the data input means for inputting program data into the program means and data output from the second read means for read from the second block means are performed at a same terminal via same data input/output means.

24. A signal processing system comprising:
the nonvolatile semiconductor memory device of claim 21; and
an operation LSI connected to the nonvolatile semiconductor memory device via an address bus and a data bus.
